(19) United States
(12) Patent Application Publication
(10) Pub. No.: US 2024/0128389 A1
(43) Pub. Date: Apr. 18, 2024

(54) LANTHANIDE-DOPED MATERIALS FOR THE DESIGN AND FABRICATION OF PV SOLAR PANELS WITH IMPROVED ENERGY EFFICIENCY

(71) Applicant: SAUDI ARABIAN OIL COMPANY, Dhahran (SA)

(72) Inventors: Aziz Fihri, Paris (FR); Yassine Malajati, Beachwood, OH (US); Remi Mahfouz, Dhahran (SA); Hamad AL Essa, Dhahran (SA)

(73) Assignee: SAUDI ARABIAN OIL COMPANY, Dhahran (SA)

(21) Appl. No.: 18/540,470

(22) Filed: Dec. 14, 2023

Related U.S. Application Data
(62) Division of application No. 17/834,555, filed on Jun. 7, 2022.

(51) Int. Cl. H01L 31/048; H01L 31/0352

(52) U.S. Cl. CPC H01L 31/0481; H01L 31/035236; B82Y 30/00

(57) ABSTRACT

A layered photovoltaic device and a composition for a topcoat of a photovoltaic device are described. The layers of the photovoltaic device include a topcoat and a silicon cell. The topcoat includes one or more first nanoparticles and a polymer. The first nanoparticles comprise a lattice material and two or more Lanthanide ions. The topcoat composition comprises a polymer and one or more first nanoparticles dispersed within the polymer. The one or more nanoparticles comprise a lattice including a first material comprising ytterbium.

### BACKGROUND

The current market is dominated by rigid crystalline silicon-based photovoltaic systems that are typically composed of a rigid aluminum frame, a glass front sheet, silicon cell, encapsulant and fluorinated polymers as a back-sheet. One of the main challenges afflicting the solar industry is related to the energy mismatch between the solar radiation and the band gap of crystalline silicon. This energy mismatch is responsible for substantial energy losses, limiting the maximum theoretical efficiency of solar cells to about 30% (Shockley-Queisser limit).

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In one aspect, embodiments disclosed herein relate to a layered photovoltaic device comprising two or more layers, these layers comprising a topcoat and a silicon cell. The topcoat comprises one or more first nanoparticles and a polymer. The first nanoparticles comprise a lattice material and two or more Lanthanide ions.

In a further aspect, one or more embodiments disclosed herein relate to a composition for a topcoat of a photovoltaic device comprising a polymer and one or more first nanoparticles dispersed within the polymer. The one or more nanoparticles comprise a lattice including a first material that comprises Ytterbium.

Other aspects and advantages of the claimed subject matter will be apparent from the following description and the appended claims.

### BRIEF DESCRIPTION OF DRAWINGS

FIG. 1 is a depiction of a prior art photovoltaic device.

FIG. 2 is a depiction of energy levels in down conversion in one or more embodiments.

FIG. 3 is a depiction of one or more embodiments of a topcoat of a photovoltaic device.

FIG. 4 is a depiction of one or more embodiments of a photovoltaic device.

### DETAILED DESCRIPTION

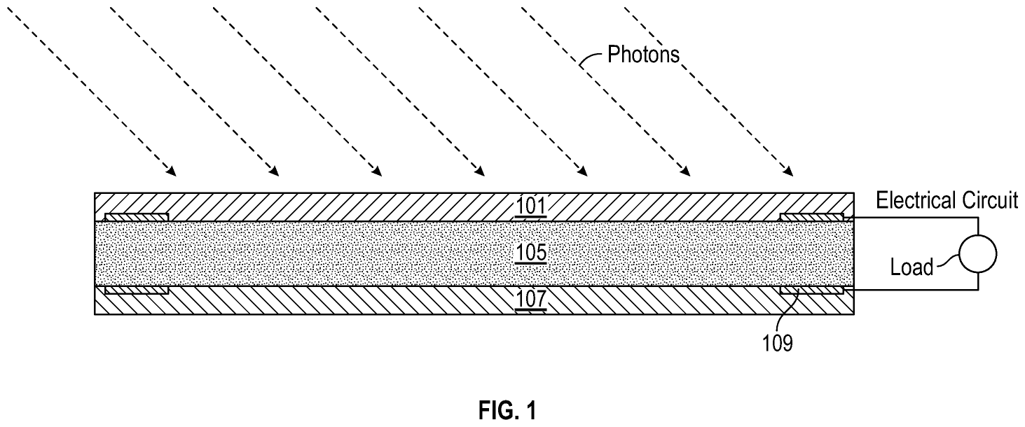

FIG. 1 is a depiction of a prior art photovoltaic device. The photovoltaic device includes one or more front layers 101, such as glass, silicon cells 105 such as n-type silicon and p-type silicon, one or more back layers 107, and electrical connectors 109. The n-type silicon layer has an excess of electrons, and the p-type silicon layer has an excess of vacancies of electrons, or “holes.” Photons from one or more light sources, such as the sun, travel through the front layers 101 to the silicon cells 105, where electrons are excited into the conduction band. Electrons travel through the circuit, through the load, and back to the silicon cells. The front layers 101 may include a number of layers with differing functions, including, but not limited to, protection and anti-reflection, and the back layers 107 may include a number of layers with differing functions including, but not limited to, protection and reflective coatings.

As noted in the Background above, crystalline silicon may be utilized as a semiconductor in photovoltaic devices to convert solar energy to electrical energy. However, there is an energy mismatch between solar radiation and the 1.1 eV band gap of crystalline silicon, which is the most abundantly used semiconductor in photovoltaics. As a result, photons from solar radiation may produce charge carriers with an energy that is significantly higher than that of the conduction band of the p-type material of the photovoltaic device, causing energy loss. This energy mismatch and subsequent loss is responsible for substantial energy losses. This is particularly true for the case of semiconductors with a small energy bandgap. Photons with energy smaller than the band gap are not absorbed, and their energy is totally wasted.

Embodiments disclosed herein utilize a lanthanide-doped topcoat or polymer layer in glass-free photovoltaic devices for up-conversion and/or down-conversion to improve the efficiency of crystalline silicon photovoltaic devices. The use of Lanthanide-doped nanoparticles allows for less energy loss from absorption of photons with energies that are significantly higher than that of the conduction band. When Lanthanide-doped nanoparticles are placed in a film and used as a covering layer for a photovoltaic device, this enables redistribution of energy. In addition, in one or more embodiments, the use of a polymer film as a topcoat for a photovoltaic device may reduce weight when compared to photovoltaic devices using glass as a topcoat.

In some embodiments, the combination of two different kinds of nanoparticles are incorporated into a polymer matrix. The result is a material that can be used as coating and/or a top layer on the front sheet of PV solar panels to primarily enhance the overall efficiency of the solar panels by redistributing the energy of the solar irradiation, such as by up conversion and/or down conversion, as well as potentially improving other properties such as scratch resistant, hardness, etc. Embodiments herein present an alternative approach to design new PV solar panels with enhanced efficiency, including lightweight glass-free solar panels that offer several attributes such as ease of installation and transportation and cost-efficiency.

A process known as down-conversion may be used to transform higher energy photons into lower energy photons that have an energy closer to that of the bandgap, reducing losses. Down-conversion is achieved by combining two lanthanide ions, one capable of absorbing a high energy photon (donor) and one able to emit a low energy photon (acceptor). A combination of two different types of Lanthanide ions allow for one Lanthanide ion, known as a donor, to absorb a higher energy photon and for another Lanthanide ion, known as an acceptor, to emit a lower energy photon. Energy is transferred from the donor to the acceptor during this process. The process of down-conversion is non-radiative and does not involve thermal loss if the energy mismatch between the immediate energy levels of the donor and the acceptor is minimal or near to nil. In particular cases, if the energy of the absorbed photon is double the energy of the down converted photon, one electron could be converted into 2 electrons, thus considerably increasing the potential efficiency of the solar cell. Lanthanide ions are suitable for this type of process. These ions are characterized by narrow and intense electronic transitions mainly induced and allowed by odd crystal field components.

In the case of photovoltaics based on silicon, ytterbium ions Yb³⁺ are suitable due to their ²F_{5/2} energy level being close to that of the band gap of silicon. Considering the energy band gap of silicon, the most suitable acceptor appears to be ytterbium ion Yb³⁺, thanks to its energy level ²F_{5/2} at around 10000 cm⁻¹ corresponding to an emission of about 1000 nm. As for the donor, it is required that an ion has an intermediate energy level at approximately the same energy as the ²F_{5/2} level of the Yb³⁺, and an energy level at about twice that (about 20000 cm⁻¹). The closer the energy between the levels of these two ions, the more efficient the energy transfer, in this case the down-conversion. If a Lanthanide ion has an energy level that is about twice that of an acceptor's energy level, and another energy level that is about the same as that of the acceptor's energy level, then down conversion is possible. As the energy levels of the two ions will not be exactly the same, some energy loss may occur during down conversion, with energy levels closer in energy between the two ions causing less energy loss during down conversion. In some embodiments, suitable donors may include, but are not limited to, Lanthanide ions such as praseodymium ion Pr³⁺, erbium ion Er³⁺, neodymium ion Nd³⁺, holmium ion Ho³⁺, terbium ion Tb³⁺ and thulium ion Tm³⁺.

Similarly, the use of appropriate Lanthanide ions may provide for up-conversion. Up-conversion is a process in which low energy photons are transformed into high energy photons. In one or more embodiments, up-conversion would be utilized to convert low energy photons into high energy photons that more closely match the energy of the bandgap. Here, two low-energy photons are added up to give one higher energy photon. Lanthanide ions are suitable for this type of process as well, as they are characterized by narrow and intense electronic transitions mainly induced and allowed by odd crystal field components. Up-conversion may be achieved through the use of Yb³⁺ as an acceptor, for example. Up-conversion and down-conversion processes can take place within a single type of dopant ion, or they can involve energy transfer between two or more types of ions co-doped within the same host material.

Several lattices may be suitable for down-conversion or up-conversion upon doping with the donor and acceptor Lanthanide ions. In one or more embodiments, these lattices should not be significantly structurally changed by the Lanthanide ions. If the lattices are significantly structurally changed by the addition of Lanthanide ions, a crystalline disorder may be caused which results in partially removing the degeneration of the Stark levels. This will lead to broader energy bands, energy levels spanning over a range of energies and reduction of the transition dipole moment at the specific energy. In other words, the requirement for the down-conversion will disappear and will affect the intensity of the transition, thus decreasing the down-conversion or up-conversion probability. In one or more embodiments, the lattice vibrations should allow for the energy levels of the donor and the acceptor to be bridged, but the lattice vibrations should not be so large that there is competition between the multiphoton relaxation and the down-conversion or up-conversion process. In the case of Er³⁺ and Pr³⁺, the donor and the acceptor energy levels are close enough in value that they do not require the assistance of lattice vibrations for down-conversion. The combination of these properties increases the probability of down-conversion or up-conversion. In one or more embodiments, suitable lattices may include, but are not limited to fluorides such as: SrF₂, YF₃, NaYF₄, LiYF₄, and NaGdF₄. In one or more embodiments, suitable lattices may include, but are not limited to bromides such as CsCdBr₃. In one or more embodiments, suitable lattices may include, but are not limited to, inorganic metal oxides such as silicon oxide, titanium oxide, or zinc oxide.

Because different lattices increase the probability of down-conversion and up-conversion, Lanthanide-doped nanoparticles may be introduced into a topcoat on the front sheet of photovoltaic devices. This topcoat may comprise a polymer and one or more Lanthanide-doped nanoparticles. In one or more embodiments, these nanoparticles may have a size that is less than or equal to about 50 nm. In one or more embodiments, these nanoparticles may have a size between 5 nm and 10 nm. In one or more embodiments, the doping level of the Lanthanides in the lattice may be between about 0.1% and about 50%, by weight. In one or more embodiments, the range of doping levels of the Lanthanides in the lattice may have an upper limit of any of about 50 wt. %, 40 wt. %, 30 wt. %, or about 20 wt. % and a lower limit of any of about 0.1 wt. %, 1 wt. %, or about 2 wt. %, with any upper limit being combinable with any lower limit.

In some embodiments, the Lanthanide-doped nanoparticles may be associated with other nanoparticles that are used to enhance the properties (scratch resistance, yellowing, etc.) of the polymer film layer. For example, the Lanthanide-doped nanoparticles may be associated with SiO₂ particles, TiO₂ particles, or ZnO particles, among others, when added to the polymer and formed into a film.

Polymer films for a topcoat may be used in photovoltaic devices. These polymers may comprise one or more of the following: thermoplastics, thermosets fiber-reinforced plastic, elastomers, composites, vitrimers, latex-based polymers, and silicone-based polymers. In one or more embodiments, suitable polymers may include, but are not limited to polyurethane dispersions. In one or more embodiments, suitable polymers may include, but are not limited to fluorinated compounds. Other polymers known to those skilled in the art may also be utilized. Some examples of thermoplastic polymers that may be utilized in one or more embodiments may include, but are not limited to, poly(methyl methacrylate) (PMMA), polycarbonate (PC), and polyethylene terephthalate (PET). In one or more embodiments, the polymer may also include fibers, such as glass fibers, as fiber reinforced composites. The above-described nanoparticles may be dispersed in the polymer matrix through any known mixing and compounding methods, including, but not limited to, melt mixing, solvent mixing, and milling.

Polymer films formed from one or more of the above-noted polymers, when doped with nanoparticles, should have sufficient optical properties (clarity, transmission, etc.) for use in a solar cell. Suitable thicknesses of the polymer layer, concentrations of nanoparticles within the polymer matrix, etc., may thus be dependent upon the particular polymer type, particle type, particle size, and other system variables, as would be readily recognized by one skilled in the art. For example, in one or more embodiments, the loading of nanoparticles in the film may be considered to have a significant effect on the optical properties if the reduction in the optical transmittance is about 20% or more over the base polymer.

In one or more embodiments, the polymer film may additionally comprise undoped nanoparticles. These undoped nanoparticles may comprise zinc oxide, titanium oxide, silicon oxide, or any combination of these, and may be added to the polymer film to improve scratch resistance of the polymer film without affecting its transparency. For this reason, the size of such nanoparticles may be below 50 nm in one or more embodiments. In one or more embodiments, the range of the combined loading of the doped and undoped nanoparticles may have an upper limit of any of about 20 wt. %, 15 wt. %, or 10 wt. %, and a lower limit of any of about 0.1 wt. %, 1 wt. %, or 2 wt. %, with any upper limit being combinable with any lower limit.

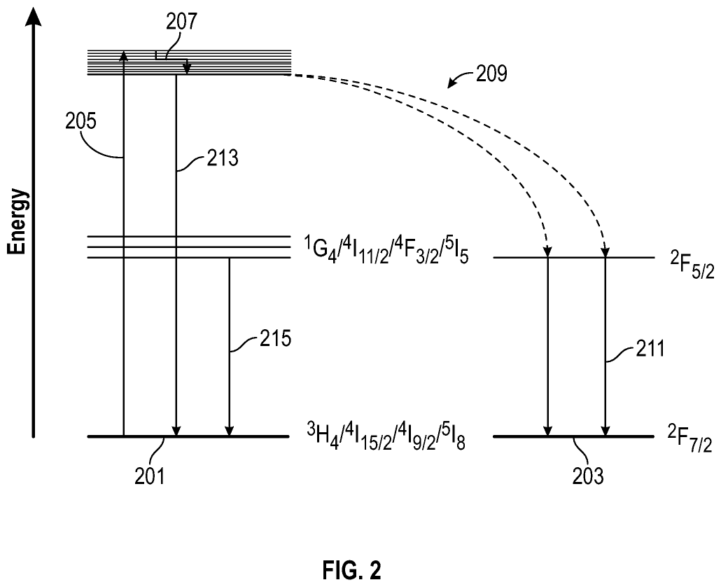

FIG. 2 is a depiction of energy levels in down-conversion that may result in one or more embodiments herein. FIG. 2 shows the energy levels of the donor Lanthanide ion 201 and the energy levels of the acceptor Lanthanide ion 203. In FIG. 2, a photon causes excitation 205 after being absorbed by the donor Lanthanide ion 201. Energy is lost via multi-phonon relaxation 207 before being transferred 209 to two acceptor Lanthanide ions 203. Down conversion 211 occurs as two photons are emitted as the energy in the acceptor Lanthanide ion 203 drops from the ²F_{5/2} energy level to the ²F_{7/2} energy level. Other emissions 213, 215 may occur as a result of the donor Lanthanide ion excitation 205 such as emission after multi-phonon relaxation 213 or emission after other energy loss 215. In FIG. 2, the donor Lanthanide ion 201 has an intermediate energy level at approximately the same energy as the ²F_{5/2} level of the acceptor Lanthanide ion Yb³⁺.

FIG. 2 is a depiction of one or more embodiments. Energy levels in other embodiments may have other configurations. For example, in one or more embodiments, other Lanthanide ions and other energy levels may be utilized to facilitate down-conversion or up-conversion.

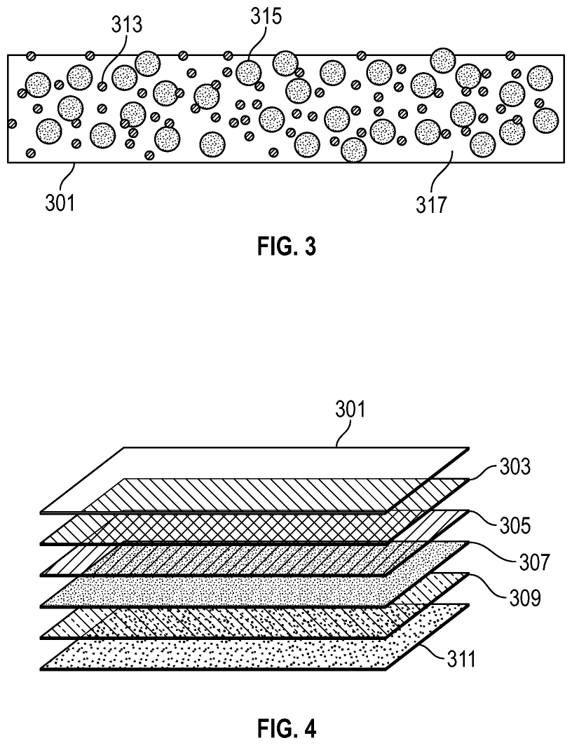

FIG. 3 is a depiction of one or more embodiments of a topcoat of a photovoltaic device. The topcoat 301 comprises two different types of nanoparticles embedded in a polymer matrix 317, specifically down-conversion Lanthanide-doped nanoparticles 313 and metal-oxide nanoparticles 315. In the embodiments of FIG. 3, the size of the down-conversion Lanthanide-doped nanoparticles 313 is between 5-10 nm but can extend to 50 nm in one or more embodiments. In the embodiments of FIG. 3, a number of host lattice materials may be used in the down-conversion Lanthanide-doped nanoparticles 313, including but not limited to inorganic metal oxides such as silicon oxide, titanium oxide, or zinc oxide, fluorides such as SrF₄, YF₃, NaYF₄, LiYF₄, or NaGdF₄, or bromides such as CsCdBr₃. In the embodiments of FIG. 3, the size of the metal oxide nanoparticles may be below 50 nm. In the embodiments of FIG. 3, metal oxide nanoparticles may comprise silicon oxide, titanium oxide, or zinc oxide. The polymer used to produce the polymer matrix 317 may include poly(methyl methacrylate), polycarbonate (PC), or polyethylene terephthalate (PET). The loading of metal-oxide nanoparticles 315 and Lanthanide-doped nanoparticles 313 in the topcoat 301 may vary as long as the optical properties of the final material are not significantly affected.

FIG. 3 is a depiction of one or more embodiments. Other embodiments may be possible. For example, the polymer matrix may further include fibers, producing a topcoat comprising a fiber reinforced composite.

FIG. 4 is a depiction of one or more embodiments of a photovoltaic device. Layers are shown separated from each other for clarity, but, when formed into a photovoltaic device, these layers are in contact with each other in the configuration shown in this embodiment. In this embodiment, there is a topcoat 301 comprising Lanthanide-doped nanoparticles 313, metal-oxide nanoparticles 315, and a polymer matrix 317. The topcoat 301 is on the distal side of a front sheet 303 from silicon cells 307. Bounded by the front sheet 303 and the silicon cells 307 is a front encapsulant 305. The front sheet 303 is thus bounded by the topcoat 301 and the front encapsulant 305. On the opposite side of the silicon cells 307 from the topcoat 301 is a back encapsulant 309 attached to the silicon cells 307, meaning that the silicon cells 307 are bounded by the front encapsulant 305 and the back encapsulant 309. On the side of the back encapsulant 309 that is distal from the silicon cells 307 is a back sheet 311. The back encapsulant 309 is thus bounded by the silicon cells 307 and the back sheet 311. Electrical contacts would be present in the silicon cells.

FIG. 4 is a depiction of one or more embodiments. Other arrangements and embodiments evident to those with skill in the art may be possible. For example, one or more of the shown layers may be combined or removed. Additional layers or components may be added as well. The front sheet or other layers may comprise inorganic glass or other materials, rather than polymeric materials.

As described above, embodiments herein provide materials that can be used as component in the fabrication of new solar panels with enhanced efficiency. The main benefits of these materials are to increase the energy conversion efficiency of the panel, decrease the overall weight of the system, and improve the resilience of the topcoat and outer layer(s). These new materials include a polymer matrix filled with lanthanides-doped nanoparticles enabling energy redistribution. Several polymers can be suitable for this purpose, including but not limited to acrylics/latexes, polyurethane dispersions (PUDs), fluorinated compounds, silicone-based etc. The types of solar cells that may be used in embodiments herein include, but are not limited to, crystalline silicon-based solar cells, including monocrystalline, polycrystalline, and Passivated Emitter and Rear Cells (PERC).

In the case of glass free solar panels, polymer-based materials according to embodiments herein can be used as front-sheet to replace glass. The use of these polymers is advantageous because they greatly reduce significantly the weight of the solar panel, reduce its overall lifecycle cost, and in certain cases also confer flexibility to the panel. However, polymers typically have lower performance for scratch resistance and yellowing. Examples of polymers that can be used include, but are not limited to poly(methyl methacrylate) (PMMA), polycarbonate (PC), polyethylene terephthalate (PET), etc. They can also be used in combination with fibers as fiber reinforced composites (e.g. glass fibers, etc.). To overcome some of the drawbacks listed above, the addition of nanoparticles such as silica, titania, ZnO, etc. have been shown to improve scratch resistance and to a certain extend delay the yellowing effect to which the polymers are prone. Embodiments herein thus solve various challenges afflicting the solar industry, including material performance as well as the energy mismatch between the solar radiation and the 1.1 eV band gap of crystalline silicon, which is the most abundantly used semiconductor in photovoltaics.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. § 112(f) for any limitations of any of the claims herein, except for those in which the claim expressly uses the words ‘means for’ together with an associated function.

What is claimed:

1. A layered photovoltaic device comprising:
a silicon cell; and
a topcoat comprising:
one or more first nanoparticles, wherein the one or more first nanoparticles comprises a lattice material and two or more Lanthanide ions; and
a polymer.

2. The layered photovoltaic device of claim 1, wherein the topcoat further comprises one or more second nanoparticles, the one or more second nanoparticles comprising a second material selected from the group consisting of silicon oxide, titanium oxide, and zinc oxide.

3. The layered photovoltaic device of claim 1, wherein the topcoat is configured to promote up-conversion or down-conversion to match an energy bandgap of the silicon cell.

4. The layered photovoltaic device of claim 1, wherein one of the two or more Lanthanide ions is Ytterbium.

5. The layered photovoltaic device of claim 4, wherein the two or more Lanthanide ions further comprise an element selected from the group consisting of: praseodymium, erbium, neodymium, and holmium.

6. The layered photovoltaic device of claim 1, wherein the lattice material is selected from the group consisting of silicon oxide, titanium oxide, and zinc oxide.

7. The layered photovoltaic device of claim 1, wherein the lattice material is selected from the group consisting of SrF₄, YF₃, NaYF₄, LiYF₄, and NaGdF₄.

8. The layered photovoltaic device of claim 1, wherein the lattice material comprises CsCdBr₃.

9. The layered photovoltaic device of claim 1, further comprising a front sheet, a front encapsulant, a back encapsulant, and a back sheet.

10. The layered photovoltaic device of claim 9, wherein the front sheet is bounded by the topcoat and the front encapsulant.

11. The layered photovoltaic device of claim 9, wherein the back encapsulant is bounded by the silicon cell and the back sheet.

12. The layered photovoltaic device of claim 9, wherein the front encapsulant is bounded by the front sheet and the back encapsulant.

13. The layered photovoltaic device of claim 9, wherein the silicon cell is bounded by the front encapsulant and the back encapsulant.

14. A layered photovoltaic device, comprising:
a back sheet;
a back encapsulant;
a silicon cell;
a front encapsulant;
a front sheet; and
a topcoat, comprising:
one or more first nanoparticles, wherein the one or more first nanoparticles comprises a lattice material and two or more Lanthanide ions;
one or more second nanoparticles, the one or more second nanoparticles comprising a second material selected from the group consisting of silicon oxide, titanium oxide, and zinc oxide; and
a polymer.

15. The layered photovoltaic device of claim 14, wherein one of the two or more Lanthanide ions is Ytterbium.

16. The layered photovoltaic device of claim 15, wherein the two or more Lanthanide ions further comprise an element selected from the group consisting of: praseodymium, erbium, neodymium, and holmium.

17. The layered photovoltaic device of claim 14, wherein the lattice material is selected from the group consisting of silicon oxide, titanium oxide, and zinc oxide.

18. The layered photovoltaic device of claim 14, wherein the lattice material is selected from the group consisting of SrF₄, YF₃, NaYF₄, LiYF₄, and NaGdF₄.

19. The layered photovoltaic device of claim 14, wherein the lattice material comprises CsCdBr₃.

20. The layered photovoltaic device of claim 14, wherein the topcoat is configured to promote up-conversion or down-conversion to match an energy bandgap of the silicon cell.
